(19) United States
(12) Patent Application Publication
(10) Pub. No.: US 2016/0034084 A1
(43) Pub. Date: Feb. 4, 2016

(54) TOUCH DISPLAY DEVICE

(71) Applicant: ASUSTeK COMPUTER INC., Taipei City (TW)

(72) Inventors: Chin-An Tseng, Taipei City (TW); Yung-Ming Huang, Taipei City (TW); Mien-Mien Cheng, Taipei City (TW)

(21) Appl. No.: 14/806,671

(22) Filed: Jul. 23, 2015

Related U.S. Application Data
(60) Provisional application No. 62/031,849, filed on Jul. 31, 2014.

(30) Foreign Application Priority Data
Jun. 9, 2015 (CN) 201510312121.4

(51) Int. Cl. G06F 3/041; H01L 51/52; H01L 27/32; G02F 1/1333; G02F 1/1335

(52) U.S. Cl. CPC G06F 3/0412; G02F 1/13338; G02F 1/133528; H01L 27/323; H01L 51/5293

(57) ABSTRACT

A touch display device is provided. The touch display device includes a display panel and a touch panel. The display panel displays a display image with a linear-polarized state, and includes an upper polarizer with a transmission axis. The touch panel is disposed on the display panel. The touch panel includes a substrate with a fast axis. The display image is converted from the linear-polarized state to the circular-polarized state when the passing through the fast axis. A touch display device having a plurality of substrates is provided. Since the substrate having the fast axis replaces the original substrate of the touch panel without adding an additional substrate, the touch display device is thinner.

### CROSS-REFERENCE TO RELATED APPLICATION

This application claims the priority benefit of U.S. provisional application Ser. No. 62/031,849, filed on Jul. 31, 2014 and China application serial No. 201510312121.4, filed on Jun. 9, 2015. The entirety of each of the above-mentioned patent applications is hereby incorporated by reference herein and made a part of specification.

### BACKGROUND OF THE INVENTION

1. Field of the Invention

The invention relates to a touch display device.

2. Description of the Related Art

As technology develops, electronic products are widely used in daily life. Most electronic products integrate with touch input devices instead of a keyboard or a mouse, which make the electronic products more portable, thin and user-friendly. For more applications, some mobile electronic devices, such as a mobile phone or a tablet, further integrate a touch panel with a display panel.

Users usually wear polarized sunglasses to view a display image on a screen of the touch display device to reduce the influence of light on eyes. However, when a polarization direction of the light of the display image is orthogonal to that of the polarized sunglasses, the user would view a completely dark display image. In detail, FIG. 1A is a schematic diagram showing sunglasses cooperating with a conventional touch display device.

Please refer to FIG. 1A; a touch display device 100 includes a display panel 110 and a touch panel 130. The display panel 110 is used to display an image. The display panel 110 includes an upper polarizer 112. The upper polarizer 112 includes a transmission axis (not shown). Since the display image of the touch display device 100 is in a linear-polarized state, when the user wears the polarized sunglasses G to look at the touch display device 100 from different viewing angles θ, the brightness viewed by the user has obvious differences with the change of the viewing angles θ of the polarized sunglasses G.

FIG. 1B is a schematic diagram showing light distribution with variation of an angle between a conventional touch display device and the polarized sunglasses G. Please refer to FIG. 1B, when an angle between the transmission axis of the upper polarizer 112 and the polarized sunglasses G is about 150° or 330°, the touch display device viewed by the user is almost dark completely.

Conventionally, a 1/4λ, wave plate is additionally disposed at the display panel, and then the display image in the linear-polarized state is converted to that in a circular-polarized state, then, when the user wears the polarized sunglasses to look at the touch display device from different angels, the brightness would not be uneven.

FIG. 2A is a cross-section diagram showing a conventional touch display device. Please refer to FIG. 2A, a touch display device 200a includes a backlight module 240a, a liquid crystal display (LCD) panel 210a, a 1/4λ wave plate 220a and a touch panel 230a in sequence. The LCD panel 210a includes a lower polarizer 216a, a liquid crystal layer 214a and an upper polarizer 212a in sequence. The 1/4λ wave plate 220a is disposed between the upper polarizer 212a and the touch panel 230a.

FIG. 2B is a diagram showing a cross-section of another conventional touch display device. Please refer to FIG. 2B, a touch display device 200b includes an organic light emitting diode (OLED) panel 210b, a 1/4λ, wave plate 220b and a cover plate 230b in sequence. The OLED panel 210b further includes an organic light emitting display layer 214b (which includes an on-cell/in-cell touch module), a lower 1/4λ, wave plate 216b and an upper polarizer 212b in sequence.

In the above touch display devices, the light in the linear-polarized state is converted to that in the circular-polarized state via the 1/4λ wave plate 220a, 220b, and then the light component at every polarization direction are almost the same. As a result, when the user wears the polarized sunglasses to look at the touch display device from different angles, the brightness is even. However, the touch display device needs an additional 1/4λ wave plate, the thickness of the touch display device is increased.

### BRIEF SUMMARY OF THE INVENTION

A touch display device is provided. The brightness can still keep adequate even when the user wears the polarized sunglasses to look at the touch display device from different angels.

The touch display device includes a display panel and a touch panel. The display panel displays a display image with a linear-polarized state and includes an upper polarizer with a transmission axis. The touch panel is disposed on the display panel, and includes a substrate with a fast axis. The display image is converted from the linear-polarized state to the circular-polarized state when passing through the fast axis.

A touch display device is also provided herein. The touch display device includes a display panel and a touch panel. The display panel displays a display image with a linear-polarized state and includes an upper polarizer with a transmission axis. The touch panel is disposed on the display panel and includes a plurality of substrates.

The each substrate has a fast axis. The fast axes of the substrates are equivalent to a fast axis assembly. The display image is converted from the linear-polarized state to the circular-polarized state when the display image passing through the fast axis assembly.

In conclusion, according to the touch panel of the touch display device in the embodiment, at least one substrate includes the fast axis. The polarization direction of the display image is converted from the linear-polarized state to the circular-polarized state when the display image passes through the fast axis of the substrate (or the fast axis assembly equivalent to the fast axes of the plurality of the substrates).

As a result, the brightness keeps adequate even when the user wears the polarized sunglasses to look at the touch display device from different angels. In the embodiments, since the substrate having the fast axis replaces the original substrate of the touch panel without adding an additional substrate, the thickness of the touch display device is reduced.

### BRIEF DESCRIPTION OF THE DRAWINGS

These and other features, aspects and advantages of the invention will become better understood with regard to the following embodiments and accompanying drawings.

FIG. 1A is a schematic diagram showing sunglasses cooperating with a conventional touch display device;

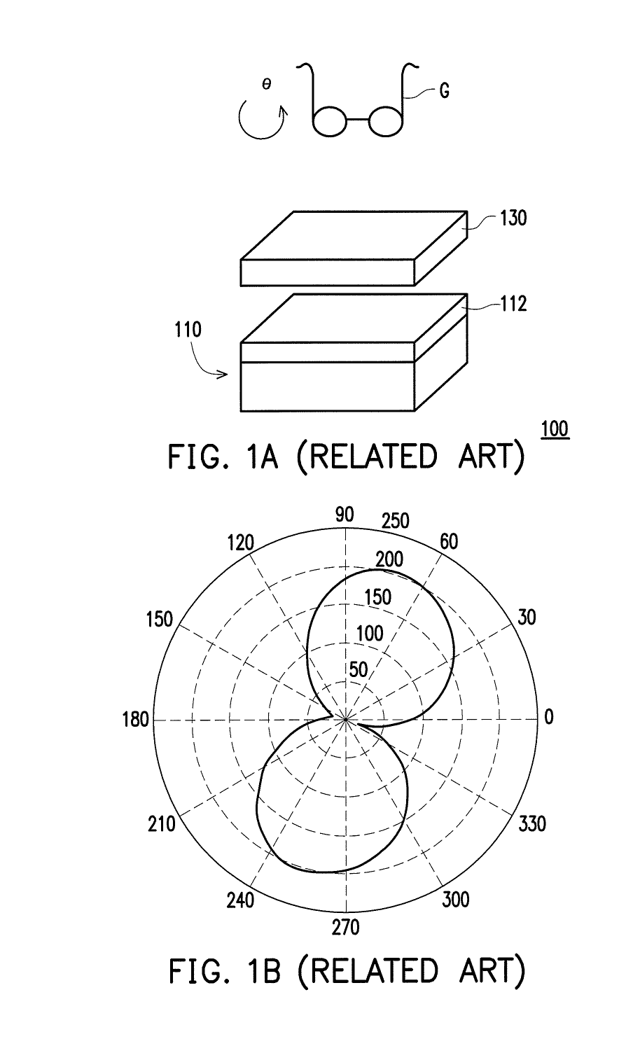

FIG. 1B is a schematic diagram showing light distribution with variation of an angle between a conventional touch display device and polarized sunglasses;

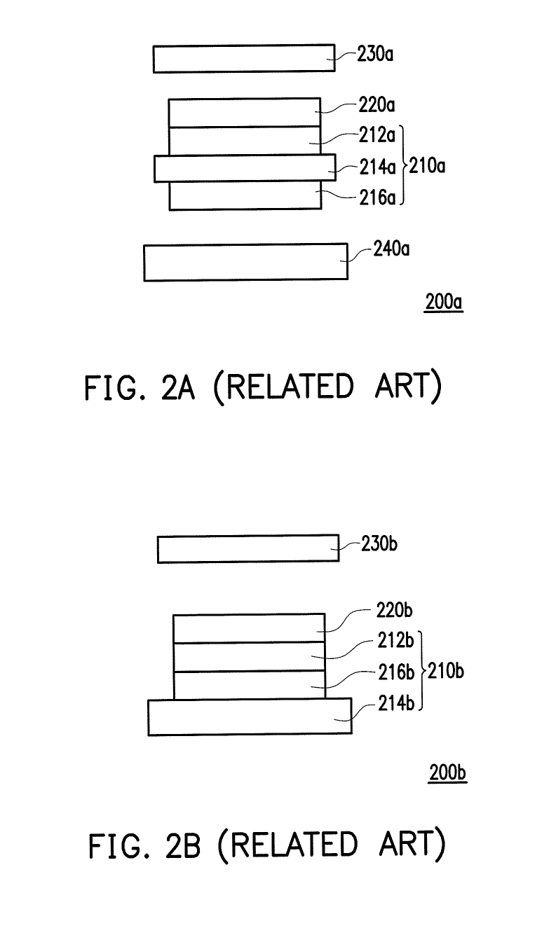

FIG. 2A and FIG. 2B are cross-section diagrams showing conventional touch display devices, respectively;

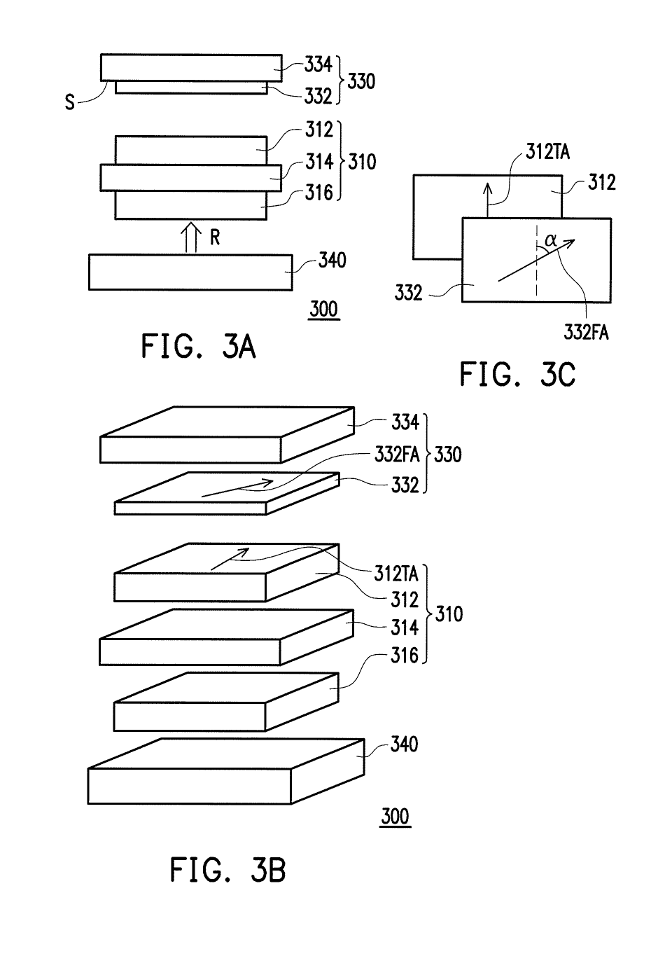

FIG. 3A, FIG. 4A, FIG. 5A and FIG. 6A are cross-section diagrams showing touch display devices in different embodiments;

FIG. 3B, FIG. 4B, FIG. 5B and FIG. 6B are exploded diagrams showing a touch display device in FIG. 3A, FIG. 4A, FIG. 5A and FIG. 6A, respectively;

FIG. 3C and FIG. 4C are top views showing an angle between a fast axis and a transmission axis of a touch display device in FIG. 3A and FIG. 4A, respectively;

FIG. 5C and FIG. 6C are top views showing an angle between a fast axis assembly and a transmission axis of a touch display device in FIG. 5A and FIG. 6A; and

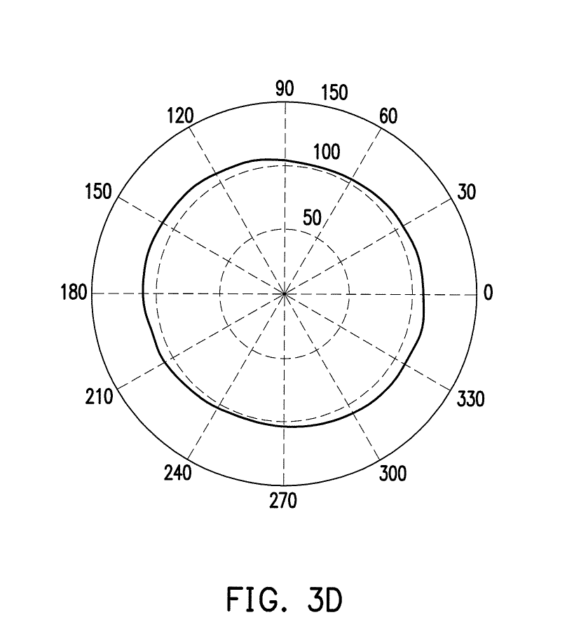

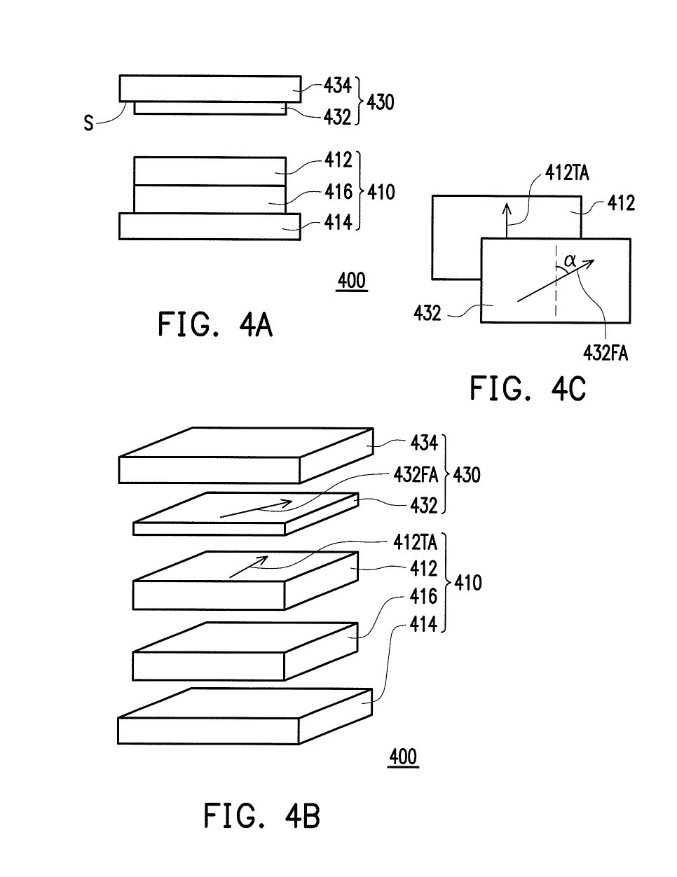

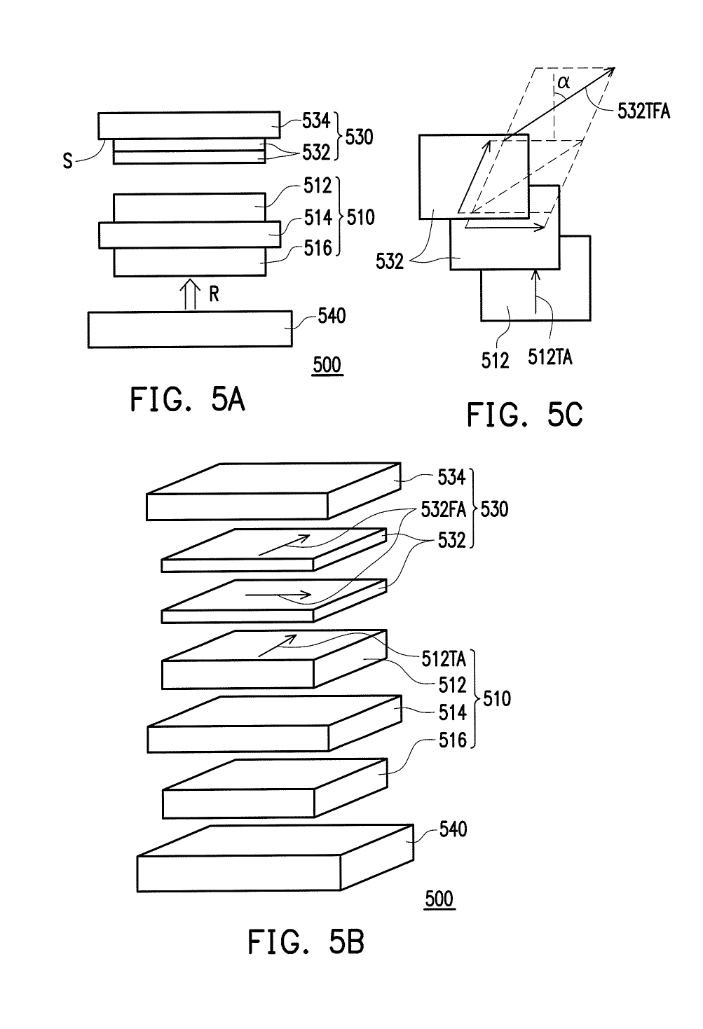

FIG. 3D is a schematic diagram showing light distribution with the variation of an angle between the touch display device and polarized sunglasses in FIG. 3A.

### DETAILED DESCRIPTION OF THE EMBODIMENTS

FIG. 3A is a cross-section diagram showing a touch display device in an embodiment. FIG. 3B is an exploded diagram showing a touch display device in FIG. 3A. FIG. 3C is a top view showing an angle between a fast axis and a transmission axis of a touch display device in FIG. 3A.

Please refer to FIG. 3A to FIG. 3C, in the embodiment, a touch display device 300 is suitable to be viewed behind a polarized element (not shown), and the polarized element is polarized sunglasses in an embodiment, which is not limited herein. The touch display device 300 includes a backlight module 340, a display panel 310 and a touch panel 330.

In the embodiment, the display panel 310 is a LCD panel. The display panel 310 includes an upper polarizer 312, a liquid crystal layer 314 and a lower polarizer 316. The liquid crystal layer 314 is disposed between the upper polarizer 312 and the lower polarizer 316. The upper polarizer 312 includes a transmission axis 312TA. The backlight module 340 is disposed below the lower polarizer 316 of the display panel 310 to provide light R to the display panel 310 to display an image.

In the embodiment, the touch panel 330 is disposed on the display panel 310, and the touch panel 330 includes a substrate 332, a cover plate 334 and a plurality of sensing electrodes (not shown). The cover plate 334 includes a surface S facing the display panel 310. The substrate 332 is disposed on the surface S. The sensing electrodes are disposed between the substrate 332 and the cover plate 334.

When the display image of the display panel 310 passes through the upper polarizer 312, the display image is transmitted out in the linear-polarized state with a particular polarization direction. In the embodiment, the touch panel 330 includes the substrate 332 having a fast axis 332FA, and an angle between the fast axis 332FA of the substrate 332 and the transmission axis 312TA of the upper polarizer 312 is neither parallel nor perpendicular. In an embodiment, an angle α between the fast axis 332FA of the substrate 332 and the transmission axis 312TA of the upper polarizer 312 is between 5° to 85° (in an embodiment, the angle α is 45°). As a result, when the display image in the linear-polarized state passes through the fast axis 332FA of the substrate 332, the display image is converted from the linear-polarized state to the circular-polarized state. The brightness of the display image can keep adequate, and the situation of completely dark in the display image would not occur when the user wears the polarized sunglasses to look at the touch display device 300.

FIG. 3D is a schematic diagram showing light distribution with variation of an angle between the touch display device and the polarized sunglasses in FIG. 3A. In FIG. 3D, the measurement results show that the brightness of the touch display panel at different viewing angles is almost the same when the user wears the polarized sunglasses to look at the touch display device 300, the brightness of the display image can keep adequate.

Compared to the conventional touch display device with an additional 1/4λ wave plate between the display panel and the touch panel, in the embodiment, the original substrate of the touch panel 330 of the touch display device 300 is used to convert the linear-polarized state to the circular-polarized state, and thus the thickness of the touch display device is reduced.

In the embodiment, the touch panel 330 includes kinds of types, such as an one glass solution (OGS) structure, a glass-film (GF) structure, a glass-film 2 (GF2) structure or a glass-film-film (GFF) structure, which is not limited herein.

In the embodiment, although the touch panel 330 only includes one substrate 332, in other embodiments, the touch panel 330 also can include a plurality of substrates, such as a glass-film-film (GFF), which is not limited herein. Only one of the substrates 332 of the touch panel 330 includes the fast axis 332FA, and the angle between the fast axis 332FA and the transmission axis 312TA of the upper polarizer 312 is between 5° to 85°, the linear-polarized state is converted to the circular-polarized state. Thus, the display image which is completely dark can be avoided when the user views from certain angles. The types of the touch panel 330 are not limited to those embodiments described above.

In the embodiment, a material of the substrate 332 is polyethylene terephthalate (PET), cyclo-olefin polymer (COP) resin or Tri-Acetyl Cellulose (TAC), or any translucent material with the fast axis 332FA, which is not limited herein. The material of the cover plate 334 is the translucent material, such as glass or plastic, which is not limited herein. In an embodiment, the cover plate 334 is omitted, and a plurality of the sensing electrodes (not shown) are disposed at the lower surface of the substrate 332, that is, the surface of the substrate 332 is facing a surface of the display panel 310.

The types of the touch display device are not limited to the above embodiments. The touch display devices in embodiments hereinafter also can be referred to above embodiments, the similar description is omitted herein.

FIG. 4A is a cross-section diagram showing a touch display device in an embodiment. FIG. 4B is an exploded diagram showing the touch display device in FIG. 4A. FIG. 4C is a top view showing an angle between a fast axis and a transmission axis of the touch display device in FIG. 4A.

Please refer to FIG. 4A to FIG. 4C, in the embodiment, a touch display device 400 is similar to the touch display device 300 in FIG. 3A to FIG. 3B, and the difference between them is that a display panel 410 of the touch display device 400 is an organic light emitting display panel. In detail, in the embodiment, the touch display device 400 includes a display panel 410 and a touch panel 430. The display panel 410 includes an upper polarizer 412, a 1/4λ wave plate 416 and an organic light emitting display layer 414. The upper polarizer 412 includes a transmission axis 412TA. The 1/4λ wave plate 416 is disposed between the upper polarizer 412 and the organic light emitting display layer 414. The organic light emitting display layer 414 provides electroluminance to make the display panel 410 displaying an image.

In the embodiment, the touch panel 430 is disposed on the display panel 410. Similarly, the touch panel 430 includes a substrate 432, a cover plate 434 and a plurality of sensing electrodes (not shown). The substrate 432 includes a fast axis 432FA. The cover plate 434 includes a surface S facing the display panel 410. The sensing electrodes are disposed between the substrate 432 and the substrate 434. In the embodiment, an angle a between the fast axis 432FA of the substrate 432 of the touch panel 430 and the transmission axis 412TA of the upper polarizer 412 is between 5° to 85° (for example, the angle α is 45°). Consequently, when the display image in the linear-polarized state passes through the fast axis 432FA of the substrate 432, the display image is converted from the linear-polarized state to the circular-polarized state, so as the situation of completely dark in the display image can be avoided when the user views from some angles.

Compared to the above embodiments, in the embodiment, the touch display panel maintains a good display performance without an additional 1/4λ, wave plate added between the display panel and the touch panel, in addition, the organic light emitting display image does not include a backlight module, and then the touch display panel is thinner and power-saving, and the view angle is wider.

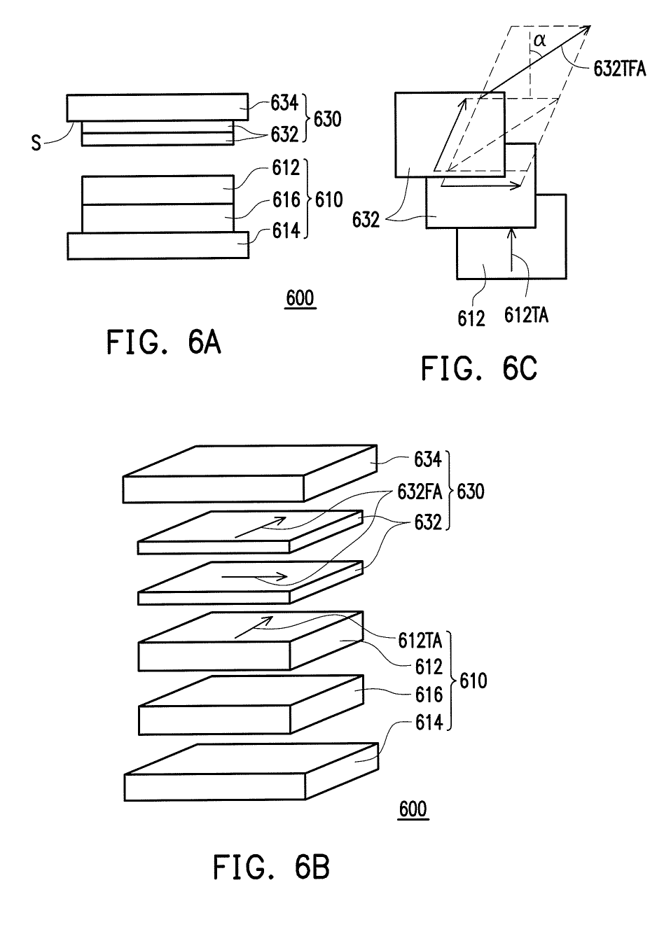

FIG. 5A is a cross-section diagram showing a touch display device in an embodiment. FIG. 5B is an exploded diagram showing the touch display device in FIG. 5A. FIG. 5C is a top view showing an angle between a fast axis and a transmission axis of the touch display device in FIG. 5A.

Please refer to FIG. 5A to FIG. 5C, in the embodiment, a touch display device 500 is similar to the touch display device 300 in FIG. 3A to FIG. 3B, the touch display device 500 includes a backlight module 540, a display panel 510 and a touch panel 530. The difference between the touch display device 500 and the touch display device 300 is that the touch panel 530 includes a plurality of substrates 532, and each substrate 532 of the touch panel 530 includes a fast axis 532FA.

In detail, the touch display device 300 only includes one substrate 332 having the fast axis 332FA. In the embodiment, the touch panel 530 includes two substrates 532, and each substrate 532 includes the fast axis 532FA, respectively. As shown in FIG. 5C, the two fast axes 532FA of the two substrate 532 are equivalent to a fast axis assembly 532TFA, and an angle a between the fast axis assembly 532TFA and the transmission axis 512TA of the upper polarizer 512 is between 5° to 85° (for example, the angle α is 45°).

In the embodiment, the touch panel 530 includes a plurality of substrates having the fast axes, and angle a between the fast axis assembly 532TFA and the transmission axis 512TA of the upper polarizer 512 is between 5° to 85°. When the display image in linear-polarized state passes through the substrates 532, the display image is converted from the linear-polarized state to the circular-polarized state, and thus the situation of completely dark in the display image can be avoided when the user views from some angles.

In the embodiment, the touch panel 530 includes a glass-film-film (GFF) structure, which is not limited herein. A plurality of first sensing electrodes (not shown) and a plurality of second sensing electrodes (not shown) of the touch panel 530 are disposed at the two substrates 532, respectively.

FIG. 6A is a cross-section diagram showing a touch display device in an embodiment. FIG. 6B is an exploded diagram showing the touch display device in FIG. 6A. FIG. 6C is a top view showing an angle between a fast axis and a transmission axis of the touch display device in FIG. 6A.

Please refer to FIG. 6A to FIG. 6C, in the embodiment, a touch display device 600 is similar to the touch display device 400 in FIG. 4A to FIG. 4B, and the difference between them is that the touch panel 630 includes a plurality of substrates 632, and each substrate 632 of the touch panel 630 includes a fast axis 632FA. In the embodiment, the touch panel 630 includes the two substrates 632, and each substrate 632 includes a fast axis 632FA, respectively.

To the display image of the display panel 610, the fast axes 632FA of the two substrates 632 are equivalent to a fast axis assembly 632TFA, and an angle a between the fast axis assembly 632TFA and the transmission axis 612TA of the upper polarizer 612 is between 5° to 85° (for example, the angle α is 45°). When the display image in the linear-polarized state passes through the substrates 632, the display image is converted from the linear-polarized state to the circular-polarized state, and thus the situation of completely dark in the display image can be avoided when the user views from some angles.

In sum, by utilizing the fast axis of one substrate or the fast axis assembly (which is equivalent to the fast axes of the substrates in the touch panel) of the touch display device, when the display image passes through the fast axis or the fast axis assembly, the polarization direction of the display image is converted from the linear-polarized state to the circular-polarized state, the brightness would not be inadequate when the user wears the polarized sunglasses to look at the touch display device from different angels. Since the substrate having the fast axis replaces the original substrate of the touch panel without adding an additional substrate, the thickness of the touch display device is reduced.

Although the main body has been disclosed with reference to certain preferred embodiments thereof, the disclosure is not for limiting the scope. Persons having ordinary skill in the art may make various modifications and changes without departing from the spirit and the scope of the invention. Therefore, the scope of the appended claims should not be limited to the description of the preferred embodiments described above.

What is claimed is:

1. A touch display device, comprising:
a display panel, displaying a display image with a linear-polarized state, and the display panel including an upper polarizer with a transmission axis; and
a touch panel, disposing on the display panel and including a substrate with a fast axis, the display image is converted from the linear-polarized state to a circular-polarized state when passing through the fast axis.

2. The touch display device according to claim 1, wherein an angle between the fast axis and the transmission axis is between 5° to 85°.

3. The touch display device according to claim 1, wherein the display panel is a liquid crystal display (LCD) panel or an organic light emitting diode (OLED) panel.

4. The touch display device according to claim 1, wherein a structure of the touch panel is an one glass solution (OGS) structure, a glass-film (GF) structure, a glass-film 2 (GF2) structure or a glass-film-film (GFF) structure.

5. The touch display device according to claim 1, wherein a material of the substrate is polyethylene terephthalate (PET), cyclo-olefin polymer (COP) resin or Tri-Acetyl Cellulose (TAC).

6. A touch display device, comprising:
a display panel, displaying a display image with a linear-polarized state and including an upper polarizer with a transmission axis; and
a touch panel, disposed on the display panel and including a plurality of substrates with fast axes equivalent to a fast axis assembly, the display image converting from the linear-polarized state to a circular-polarized state when passing through the fast axis assembly.

7. The touch display device according to claim 6, wherein an angle between the fast axis and the fast axis assembly is between 5° to 85°.

8. The touch display device according to claim 6, wherein the display panel is a LCD panel or an OLED panel.

9. The touch display device according to claim 6, wherein a structure of the touch panel is a glass-film-film (GFF) structure.

10. The touch display device according to claim 6, wherein a material of the substrate is polyethylene terephthalate (PET), cyclo-olefin polymer (COP) resin or Tri-Acetyl Cellulose (TAC).
